(19) United States
(12) Patent Application Publication
(10) Pub. No.: US 2014/0285742 A1
(43) Pub. Date: Sep. 25, 2014

(54) Display Panel and Method of Manufacturing the Same

(71) Applicant: SAMSUNG DISPLAY CO., LTD., Yongin-City (KR)

(72) Inventors: Gwan-Ha Kim, Hwaseong-si (KR); Sang-Gab Kim, Seoul (KR); Jung-Ha Son, Seoul (KR)

(73) Assignee: SAMSUNG DISPLAY CO., LTD., Yongin-City (KR)

(21) Appl. No.: 14/029,335

(22) Filed: Sep. 17, 2013

(30) Foreign Application Priority Data
Mar. 25, 2013 (KR) 10-2013-0031254

(51) Int. Cl. G02F 1/1368; H01L 27/12

(52) U.S. Cl. CPC G02F 1/1368; H01L 27/1259
USPC 349/43; 438/30

(57) ABSTRACT

A display panel includes a substrate, a first insulation layer, a first electrode, a liquid crystal layer, a second electrode and a second insulation layer. The substrate includes a thin film transistor (TFT). The first insulation layer is disposed on the substrate. The first electrode is disposed on the first insulation layer and is electrically connected to the TFT. The liquid crystal layer is disposed on the first electrode. The second electrode is disposed on the liquid crystal layer and includes a first grid structure adjacent to the liquid crystal layer. The second insulation layer is disposed on the second electrode and includes a second grid structure. Therefore, the durability of the display panel may be increased and light leakage may be prevented.

This U.S. non-provisional application claims priority under 35 U.S.C. §119 to Korean Patent Application No. 10-2013-0031254, filed on Mar. 25, 2013, the disclosure of which is incorporated by reference herein in its entirety.

### TECHNICAL FIELD

Exemplary embodiments of the present invention relate to a display panel and a method of manufacturing the same, and more particularly, to a display panel including a single substrate and a method of manufacturing the same.

### DISCUSSION OF THE RELATED ART

A display panel includes an array substrate, a color filter substrate and a liquid crystal layer disposed between the array substrate and the color filter substrate. The array substrate includes switching elements, and the color filter substrate has color filters disposed therein. Each of the array substrate and the color filter substrate includes a base substrate, thus resulting in a relatively high manufacturing cost.

An embedded micro-cavity (EM) display, panel includes switching elements and color filters on one base substrate.

Embedded micro-cavities of the embedded micro-cavity display panel contain liquid crystal. However, the structure of the embedded micro-cavities may be easily deformed while forming the embedded micro-cavities.

Furthermore, an alignment liquid that is provided in the embedded micro-cavities to form an alignment layer may clot, and this may hinder liquid crystal from being injected into the embedded micro-cavities.

### SUMMARY

In accordance with an exemplary embodiment of the present invention, a display panel includes a substrate, a first insulation layer, a first electrode, a liquid crystal layer, a second electrode and a second insulation layer.

The substrate includes a thin film transistor (TFT). The first insulation layer is disposed on the substrate. The first electrode is disposed on the first insulation layer and is electrically connected to the TFT. The liquid crystal layer is disposed between the first and second electrodes. The second electrode is disposed on the liquid crystal layer and includes a first grid structure, e.g., adjacent to the liquid crystal layer. The second insulation layer is disposed on the second electrode and includes a second grid structure.

In an exemplary embodiment of the present invention, the display panel further includes a gate line electrically connected to the TFT and extending in a first direction. The first grid structure includes a plurality of first convex portions each of which is spaced apart from each other in the first direction, and the second grid structure includes a plurality of first concave portions each of which is spaced apart from each other in the first direction. The plurality of first convex portions and the plurality of first concave portions extend in the second direction which is substantially perpendicular to the first direction.

In an exemplary embodiment of the present invention, a height of a first convex portion adjacent to an end of the liquid crystal layer is greater than a height of a first convex portion adjacent to an opposite end of the liquid crystal layer.

In an exemplary embodiment of the present invention, a width of the first convex portion adjacent to an end of the liquid crystal layer is greater than a width of the first convex portion adjacent to an opposite end of the liquid crystal layer.

In an exemplary embodiment of the present invention, a height of the first convex portion adjacent to a middle of the liquid crystal layer is greater than a height of the first convex portion adjacent to an end of the liquid crystal layer.

In an exemplary embodiment of the present invention, a width of the first convex portion adjacent to a middle of the liquid crystal layer is greater than a width of the first convex portion adjacent to an end of the liquid crystal layer.

In an exemplary embodiment of the present invention, the first grid structure further includes a plurality of second convex portions each of which is spaced apart from each other in the second direction and the second grid structure further includes a plurality of second concave portions each of which is spaced apart from each other in the second direction.

In an exemplary embodiment of the present invention, the plurality of second convex portions and the plurality of second concave portions extend in the first direction.

In an exemplary embodiment of the present invention, a height of a second convex portion adjacent to an end of the liquid crystal layer is greater than a height of a second convex portion adjacent to an opposite end of the liquid crystal layer.

In an exemplary embodiment of the present invention, a width of a second convex portion adjacent to an end of the liquid crystal layer is greater than a width of a width of a second convex portion adjacent to an opposite end of the liquid crystal layer.

In an exemplary embodiment of the present invention, the first convex portion and the second convex portion each have a right-angled corner.

In an exemplary embodiment of the present invention, the first convex portion and the second convex portion each have a rounded corner.

In an exemplary embodiment of the present invention, the first convex portion and the second convex portion each have an elliptical corner.

In accordance with an exemplary embodiment of the present invention, a method of manufacturing of a display panel is provided. A first insulation layer is foil led on a substrate. The substrate includes a thin film transistor (TFT). A first photoresist composition layer is coated on the first insulating layer, forming a sacrificial layer on the first insulation layer. A grid structure is formed on the sacrificial layer. A second insulation layer is formed on the sacrificial layer. The sacrificial layer is removed by way of a developer. A liquid crystal layer is formed in a space where the sacrificial layer removed.

In an exemplary embodiment of the present invention, a first electrode is formed on the first insulation layer, e.g., after forming the first insulation layer. A second electrode is formed on the sacrificial layer, e.g., prior to forming the second insulation layer.

In an exemplary embodiment of the present invention, a developer injection region is formed, e.g., prior to removing the sacrificial layer. The developer injection region exposes a portion of the sacrificial layer.

In an exemplary embodiment of the present invention, a second photoresist composition layer is coated on a portion of the second insulation layer. The second insulation layer is etched, exposing the sacrificial layer.

In an exemplary embodiment of the present invention, an alignment layer is formed on an inner surface of a space where the sacrificial layer is removed. A liquid crystal is injected into the space.

In an exemplary embodiment of the present invention, a sacrificial layer is formed. The sacrificial layer includes a first pattern corresponding to a template. The template has a second pattern with a plurality of protrusions on a first surface of the template. The template is separated from the sacrificial layer. A second insulation layer is formed on the sacrificial layer.

In an exemplary embodiment of the present invention, light is radiated to a mask. The mask includes a blocking area having a light blocking pattern and a slit area having a slit pattern.

In an exemplary embodiment of the present invention, light is radiated to a mask. The mask includes a blocking area having a light blocking pattern, a non-blocking area, and a transflective area having a transflective pattern.

In accordance with an exemplary embodiment of the present invention, a display panel includes a substrate, a first insulation layer, a first electrode, an image displaying layer, a second electrode and a second insulation layer.

The first insulation layer is disposed on the substrate. The first electrode is disposed on the first insulation layer. The image displaying layer is disposed on the first electrode. The second electrode is disposed on the image displaying layer and includes a plurality of convex protrusions. Each of the convex protrusions is spaced apart from each other. The second insulation layer is disposed on the second electrode.

### BRIEF DESCRIPTION OF THE DRAWINGS

The present disclosure will become more apparent by describing in detailed exemplary embodiments thereof with reference to the accompanying drawings, in which:

FIG. 1 is a plan view illustrating a display panel in accordance with an exemplary embodiment of the present invention;

FIG. 2 is a cross-sectional view taken along line I-I′ in FIG. 1;

FIG. 3 is a plan view illustrating a first pixel in the display panel of FIG. 1;

FIGS. 4A to 4D are cross-sectional views taken along line II-II′ in FIG. 3 according to exemplary embodiments of the present invention;

FIGS. 5A to 5D are plan views illustrating a first grid structure according to exemplary embodiments of the present invention;

FIGS. 6A and 6B are cross-sectional views taken along line III-III′ in FIG. 3 according to exemplary embodiments of the present invention;

FIGS. 7A to 7G are plan views illustrating a first grid structure according to exemplary embodiments of the present invention;

FIGS. 8A to 8C are partially enlarged views illustrating first and second convex portions according to exemplary embodiments of the present invention;

FIGS. 9A and 9B are cross-sectional views illustrating forming a sacrificial layer according to an exemplary embodiment of the present invention;

FIG. 10 is a cross-sectional view illustrating forming a grid structure in a sacrificial layer using a nano-imprinting process according to an exemplary embodiment of the present invention;

FIGS. 11A and 11B are cross-sectional views illustrating a method of forming a grid structure on a sacrificial layer using a slit mask according to an exemplary embodiment of the present invention;

FIGS. 12A and 12B are cross-sectional views illustrating a method of forming a grid structure on a sacrificial layer using a half-tone mask according to an exemplary embodiment of the present invention; and

FIGS. 13A to 13I are cross-sectional views illustrating a method of removing a sacrificial layer and forming an alignment layer by an alignment liquid according to an exemplary embodiment of the present invention.

### DETAILED DESCRIPTION OF THE INVENTION

Hereinafter, exemplary embodiments will be described in detail with reference to the accompanying drawings.

As those skilled in the art would realize, the described embodiments may be modified in various different ways.

In the drawings, the thickness of layers, films, panels, regions, etc., may be exaggerated for clarity. Like reference numerals may designate like or similar elements throughout the specification and the drawings. It will be understood that when an element is referred to as being “on,” “connected to,” or “coupled to” another element, it can be directly on, connected to or coupled to the other element or intervening elements may also be present.

As used herein, the singular forms “a,” “an,” and “the” are intended to include the plural forms as well, unless the context clearly indicates otherwise.

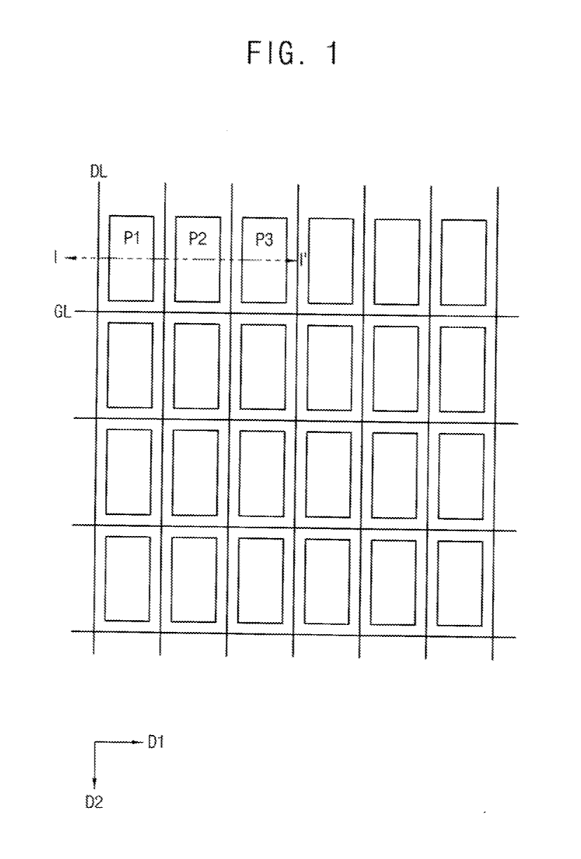

FIG. 1 is a plan view illustrating a display panel in accordance with an exemplary embodiment of the present invention.

Referring to FIG. 1, a display panel includes a plurality of gate lines GL, a plurality of data lines DL and a plurality of pixels.

The gate lines GL may extend in a first direction D1. The data lines DL may extend in a second direction substantially perpendicular to the first direction D1. Alternatively, the gate lines GL may extend in the second direction D2 and the data lines DL may extend in the first direction D1.

The pixels may be arranged in a matrix shape. The pixels may be disposed in areas defined by the gate lines GL and the data lines DL.

Each pixel may be connected to a corresponding gate line GL and a corresponding data line DL adjacent to the pixel.

Each pixel may have a rectangle shape extending in the second direction D2. Alternatively, the pixel may have a V-shape, a Z-shape, etc.

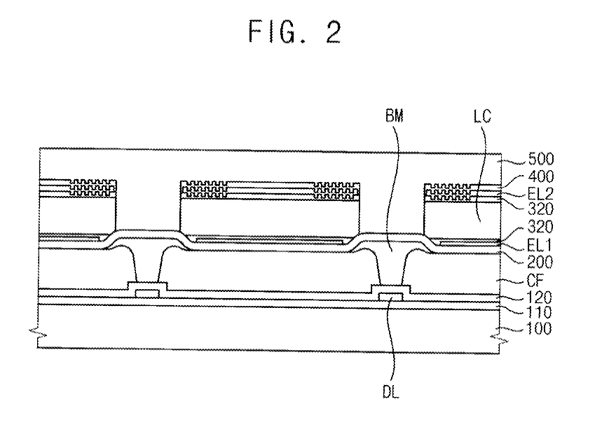

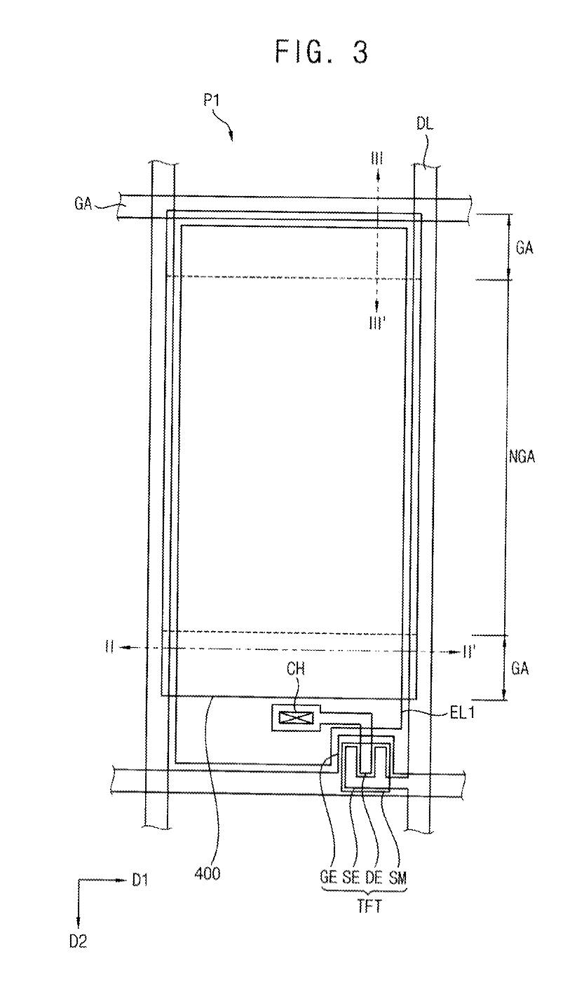

A structure of a pixel is described below in detail referring to FIGS. 2 and 3.

FIG. 2 is a cross-sectional view taken along line I-I′ in FIG. 1 according to an exemplary embodiment of the present invention. FIG. 3 is a plan view illustrating a first pixel in the display panel of FIG. 1 according to an exemplary embodiment of the present invention.

Referring to FIGS. 1 to 3, the display panel includes a substrate 100, a plurality of thin film transistors TFTs, a gate insulation layer 110, a data insulation layer 120, a color filter CF, a black matrix BM, a first insulation layer 200, a first electrode EL1, an alignment layer 320, a liquid crystal layer LC, a second electrode EL2, a second insulation layer 400 and a protection layer 500.

The substrate 100 may be a transparent insulation substrate. Examples of the transparent insulation substrate may include, but are not limited to, a glass substrate, a quartz substrate, and a plastic substrate. The substrate 100 may include a plurality of pixel areas for displaying an image. A plurality of the pixel areas may be disposed in a matrix shape having a plurality of rows and a plurality of columns.

Each pixel may further include a switching element. For example, the switching element may be a thin film transistor TFT. The switching element may be connected to the gate line GL and the data line DL adjacent to the switching element. The switching element may be disposed at a crossing area of the gate line GL and the data line DL.

A gate pattern may include a gate electrode GE and the gate line GL. The gate pattern may be disposed on the substrate 100. The gate line GL is electrically connected to the gate electrode GE.

The gate insulation layer 110 may be disposed on the substrate 100 and may cover the gate pattern.

A semiconductor pattern SM may be disposed on the gate insulation layer 110. The semiconductor pattern SM may overlap the gate electrode GE.

A data pattern may include the data line DL, a source electrode SE and a drain electrode DE. The data pattern may be disposed on the semiconductor pattern SM, which is formed on the gate insulation layer 110. The source electrode SE may overlap the semiconductor pattern SM. The source electrode SE may be electrically connected to the data line DL.

The drain electrode DE may be spaced apart from the source electrode SE on the semiconductor pattern SM. The semiconductor pattern SM may have a conductive channel between the source electrode SE and the drain electrode DE.

The TFT may include the gate electrode GE, the source electrode SE, the drain electrode DE and the semiconductor pattern SM.

The data insulation layer 120 may be disposed on the gate insulation layer 110. The data insulation layer 120 may insulate the data pattern.

The gate line GL, the data line DL and the switching element may be disposed on the gate insulation layer 110. The switching element may include the gate electrode GE, the gate insulation layer 100, the semiconductor pattern SM, the source electrode SE and the drain electrode DE. The gate insulation layer 110 may be disposed on a whole surface of the substrate 100. The gate insulation layer 110 may include an insulation material. For example, the data insulation layer 120 may include SiNx or SiOx.

The data insulation layer 120 may be disposed on the gate line GL, the data line DL and the switching element. The data insulation layer 120 may be disposed on a whole surface of the substrate 100. The data insulation layer 120 may include an insulation material. For example, the data insulation layer 120 may include SiNx or SiOx.

The color filter CE and the black matrix BM may be disposed on the data insulation layer 120.

The color filter CF may be disposed on the data insulation layer 120.

The color of light may be changed by the color filter CF and the light may penetrate the liquid crystal layer LC. Color filters CF may include a red color filter, green color filter and a blue color filter. Each color filter may correspond to one of the pixel areas. Color filters, which are adjacent to each other, may have different colors from each other.

In an embodiment of the present invention, the color filter CF may be spaced apart from a border between pixel areas adjacent to each other. Alternatively, color filters adjacent to each other may partially overlap each other on a border between pixel areas adjacent to each other.

The display panel may include signal lines and black matrixes BM. The signal lines may be connected to TFTs. The black matrixes BM may overlap the signal lines and may block light.

The black matrix BM may be disposed on an area where the gate line GL, the data line DL and the switching element are disposed. The black matrix BM may include chromium Cr and/or chromium oxide.

The first insulation layer 200 may be disposed on the color filter CF. The first insulation layer 200 may be disposed on a whole surface of the substrate 100.

The first insulation layer 200 may include an insulation material. For example, the first insulation layer 200 may include SiNx or SiOx.

The first electrode EL1 may be disposed on the first insulation layer 200. The first electrode EL1 may be disposed on a pixel area. A grayscale voltage may be applied to the first electrode EL1 through the TFT. For example, the first electrode EL1 may include a transparent conductive material, such as indium tin oxide (ITO), indium zinc oxide (TZO) and aluminum zinc oxide (AZO). For example, the first electrode EL1 may have a slit pattern. The display panel may include the alignment layer 320 to align liquid crystal molecules in the liquid crystal layer LC.

The alignment layer 320 may be disposed between the liquid crystal layer LC and the first insulation layer 200. The alignment layer 320 may be disposed between the liquid crystal layer LC and the second insulation layer 400. The alignment layer 320 pre-tilts liquid crystal molecules in the liquid crystal layer LC.

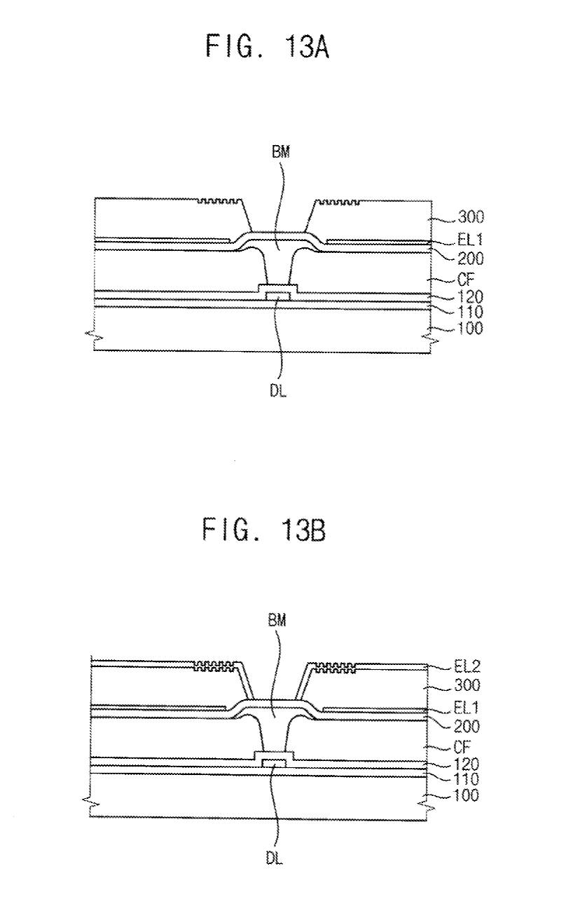

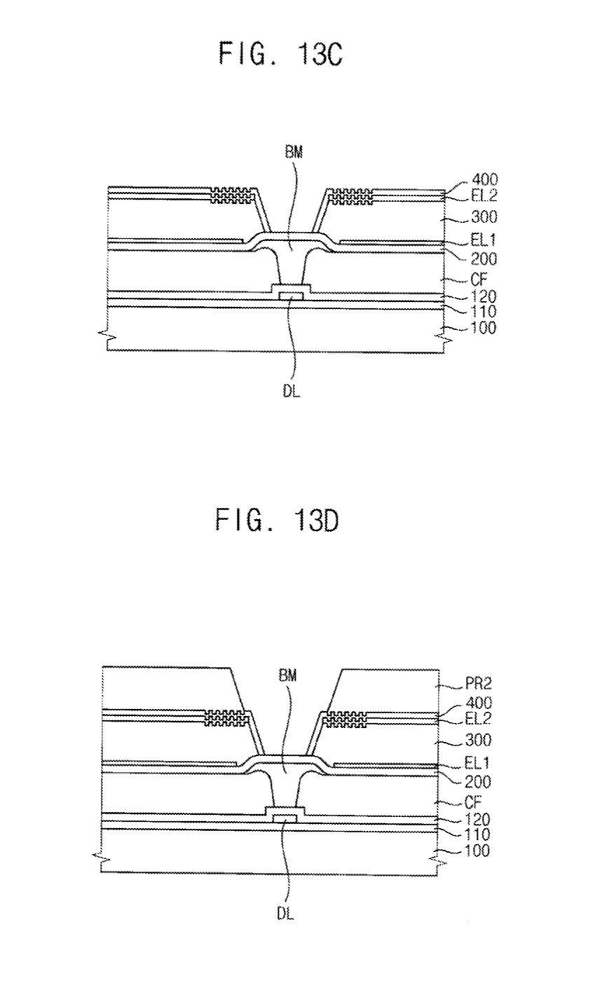

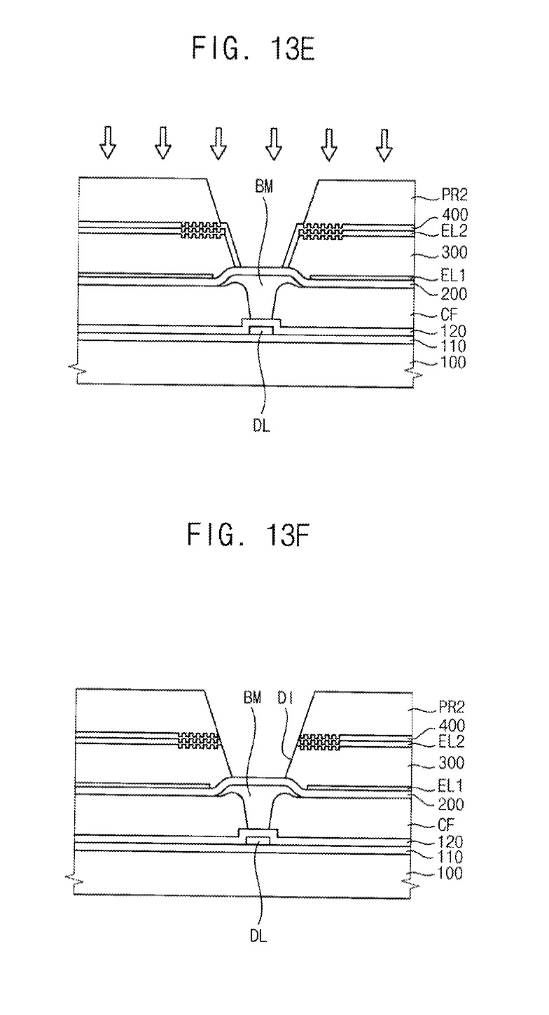

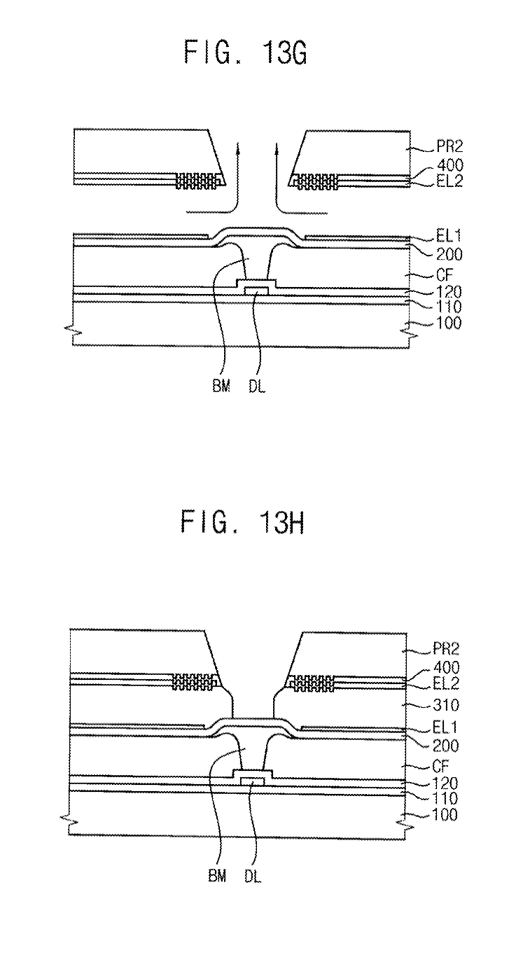

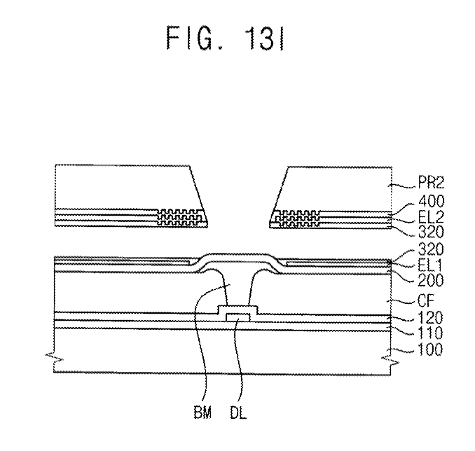

The alignment layer 320 may be formed using an alignment liquid. The alignment liquid may be provided into an embedded micro-cavity (which is also referred to as a tunnel-shaped cavity) and then the alignment liquid may be partially removed at room temperature or by heating. Forming the alignment layer 320 is described below in greater detail with reference to FIGS. 13H and 13I. When removing the alignment liquid, the alignment liquid may clot at unspecific positions in the embedded micro-cavity.

The alignment layer 320 may be disposed on an upper surface of the first insulation layer 200 and the first electrode EL1 in a tunnel-shaped cavity. The alignment layer 320 may be disposed on a lower surface of the second insulation layer 400 and the second electrode EL2 may be disposed in a tunnel-shaped cavity. The alignment layer 320 may be formed using an alignment liquid. The alignment liquid may be obtained by mixing an alignment material, such as polyimide PI, with a solvent.

The alignment liquid is a fluid, and therefore, the alignment liquid may be drawn into the tunnel-shaped cavity due to capillary action. For example, the alignment liquid may be provided into the tunnel-shaped cavity through a developer injection hole DI.

The alignment liquid may be provided into the tunnel-shaped cavity by using an inkjet process having a micropipette or a vacuum injection apparatus. After providing the alignment liquid, the alignment liquid may be removed. The substrate 100 may be maintained at room temperature or may be heated.

However, the alignment layer may be omitted in accordance with a type of the liquid crystal layer LC or a structure of the first electrode EL1 and the second electrode EL2. For example, when the first electrode EL1 has a micro slit, the liquid crystal molecules may be aligned without the alignment layer, and thus, the alignment layer 320 may be omitted. Alternatively, when a reactive mesogen layer for the liquid crystal alignment is formed, the alignment layer 320 may be omitted.

The pixel may include the first electrode EL1, the second electrode EL2 and the liquid crystal layer LC disposed between the first electrode EL1 and the second electrode EL2. An alignment of the liquid crystal molecule may be controlled by an electric field applied between the first electrode EL1 and the second electrode EL2. Therefore, a light transmittance of the pixel may be controlled.

In an exemplary embodiment of the present invention, the display panel includes the liquid crystal layer 320. Alternatively, the display panel may include an image display layer displaying an image. For example, the image display layer may be an electrophoretic layer. The electrophoretic layer may include an insulation medium and charged particles. The insulation medium may include a dispersion medium. The charged particles may include particles having electrophoretic properties. The charged particles are dispersed in the insulation medium. The charged particles may be moved in accordance with an electric field. Therefore, light that is emitted towards the electrophoretic layer may pass through the electrophorectic layer or may be blocked by the charged particles, thus displaying an image.

The second electrode EL2 may be disposed on the liquid crystal layer LC. The second electrode EL2 may include a transparent conductive material such as indium tin oxide (ITO), indium zinc oxide (IZO) and/or aluminum zinc oxide (AZO).

A grid structure may be formed in a second insulation layer 400. The second insulation layer 400 may be disposed on the second electrode EL2. The second insulation layer 400 may include an inorganic insulation material. For example, the second insulation layer 400 may include SiNx, SiOx, etc. The second insulation layer 400 may include an ultraviolet curable resin and/or a thermosetting resin.

The protection layer 500 may be disposed on the second insulation layer 400 where the grid structure is formed. The protection layer may partially surround the upper surface or a side surface of the liquid crystal layer.

The display panel may further include a first polarizer and a second polarizer. The first polarizer is disposed on a lower surface of the base substrate 110. The second polarizer is disposed on the protection layer 500.

The first polarizer may be disposed on a lower surface of the substrate 100. For example, the first polarizer may be attached on a lower surface of the substrate 100. The first polarizer may polarize light provided from a backlight assembly. The first polarizer may have a first polarized axis. The first polarizer may block light not having the first polarized axis.

A second polarizer may be disposed on the protection layer 500. For example, the second polarizer may be attached on an upper surface of the protection layer 500. Alternatively, when the protection layer 500 is omitted, the second protection layer 500 may be attached on the color filter CF and the black matrix BM. The second polarizer may polarize light that penetrates the color filter CF. The second polarizer may have a second polarized axis. The second polarized axis may be substantially perpendicular to the first polarized axis. The second polarizer may block light not having the second polarized axis.

Referring to FIGS. 3, 5A and 7A, the second insulation layer 400 and the second electrode EL2 may include a grid area GA and a non-grid area NGA. The grid area GA may have a grid structure. The non-grid area NGA might not have a grid structure.

Grid areas GA may be disposed in side portions of the second insulation layer 400 and the second electrode EL2 in the second direction D2. A non-grid area NGA may be disposed between the grid areas GAs.

The grid area GA may include a grid structure that extends in the second direction D2. Alternatively, the grid area GA may include a grid structure in which a plurality of protrusions form substantially a cross-shape (+) and extend in the first direction D1 and the second direction D2.

Due to the grid structure, the size of the second insulation layer 400 may be decreased, thus reducing the weight of the display panel. Furthermore, the second insulation layer 400 may be resistant to flexing, twisting and horizontal load, thus increasing durability.

Accordingly, the embedded micro-cavity structure may be prevented from being deformed while forming a sacrificial layer or removing the sacrificial layer.

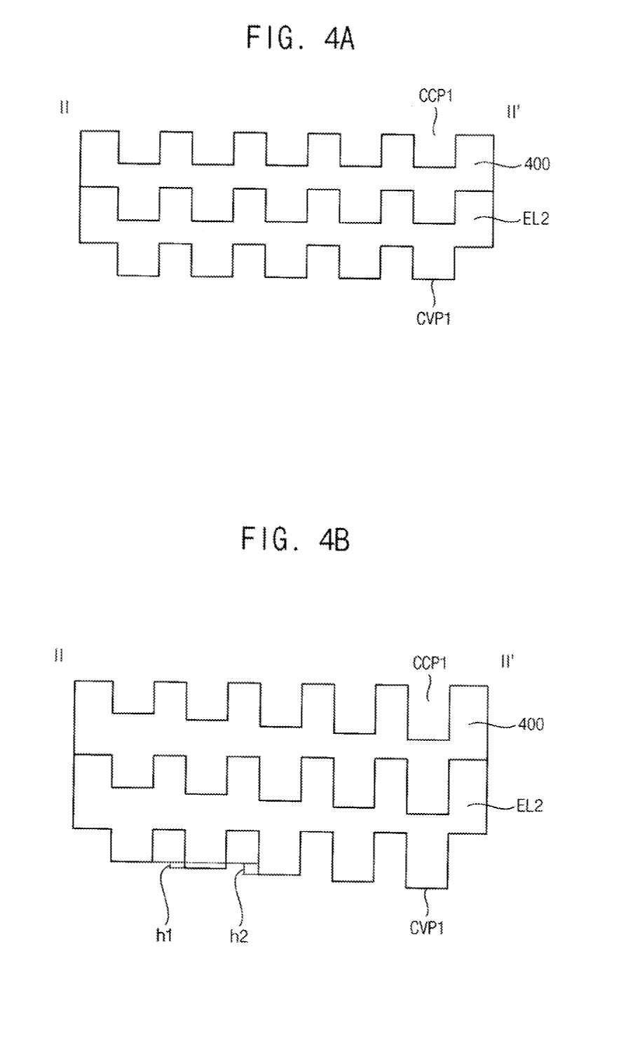

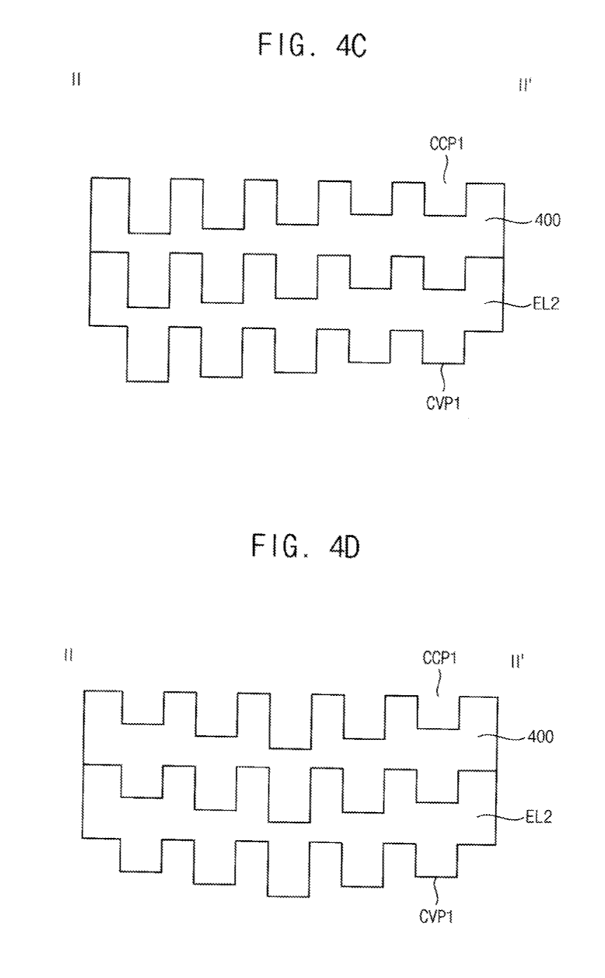

FIGS. 4A to 4D are cross-sectional views taken along line II-II′ in FIG. 3 according to exemplary embodiments of the present invention. A second electrode EL2 includes a first grid structure, and a second insulation layer includes a second grid structure.

Referring to FIGS. 3 and 4A to 4D, the first grid structure may include a plurality of first convex portions CVP1, and the second grid structure may include a plurality of first concave portion CCP1. Each of the plurality of first convex portions CVP1 may be spaced apart from each other in the first direction D1. Each of the plurality of first concave portion CCP1 may be spaced apart from each other in the first direction D1. The plurality of first convex portions CVP1 and the plurality of concave portions CCP1 may extend in a second direction D2 that is substantially perpendicular to the first direction D1.

The second grid structure may correspond to the first grid structure. For example, the second grid structure may be determined according to the first grid structure. For example, the second grid structure has substantially the same structure as the first grid structure.

Referring to FIG. 4A, the first convex portions CVP1 may have substantially the height h. The height h of the first convex portions CVP1 may be controlled in accordance with a height of the embedded micro-cavity. The height h of the first convex portions CVP1 may be about 10 um or less, for example, about 0.1 to about 5 um.

Referring to FIGS. 4B and 4C, a height of a first convex portion CVP1 adjacent to an end of the liquid crystal layer is greater than a height of a first convex portion adjacent to another end of the liquid crystal layer. For example, the height of the first convex portions CVP1 of the first grid structure may be increased in the first direction D1 of the embedded micro-cavity. Alternatively, the height of the first convex portions CVP1 of the first grid structure may be increased in an opposite direction of the first direction D1.

A first height h1 and a second height h2 each may be defined as a height difference between first convex portions CVP1 adjacent to each other. The second height h2 may be greater than the first height h1.

Therefore, when a height of a first convex portion CVP1 adjacent to an end of the liquid crystal layer is greater than a height of a first convex portion CVP1 adjacent to another end of the liquid crystal layer, the alignment liquid 310 may clot at a position where a highest first convex portion CVP1 of the first convex portions CVP1 is located. For example, the alignment liquid 310 may clot at a side surface of the embedded micro-cavity. A black matrix BM may be formed on a side surface of the embedded micro-cavity, corresponding to a non-display area. Accordingly, the display quality might not be deteriorated even though the alignment liquid 310 clots.

Referring to FIG. 4D, the height of a first convex portion CVP1 adjacent to a middle of the liquid crystal layer may be greater than the height of a first convex portion. CVP1 adjacent to an end of the liquid crystal layer.

Therefore, when a height of a first convex portion CVP1 adjacent to a middle of the liquid crystal layer is greater than a height of a first convex portion CVP1 adjacent to an end of the liquid crystal layer, the alignment liquid 310 may clot at a position where a highest first convex portion CVP1 of the first convex portions CVP1 is located or the alignment liquid 310 may barely clot. For example, the alignment liquid 310 may clot at a middle of the embedded micro-cavity or the alignment liquid 310 may barely clot.

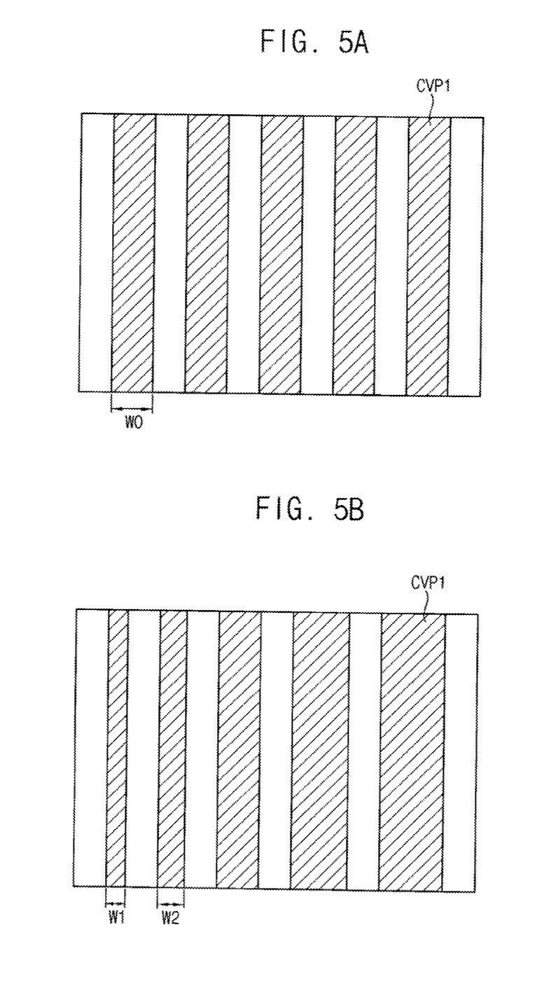

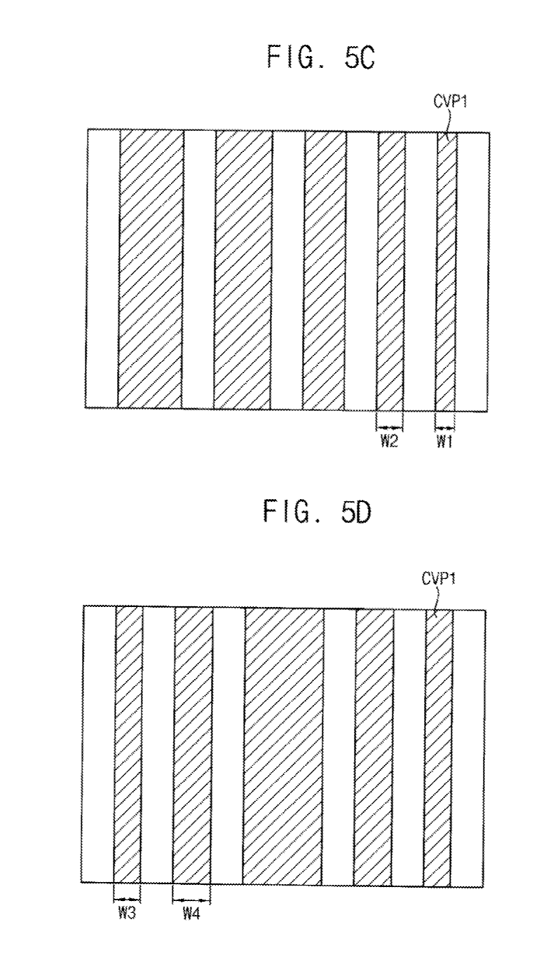

FIGS. 5A to 5D are plan views illustrating grid structures according to exemplary embodiments of the present invention. The second grid structure may be substantially similar to the first grid structure. Moreover, the arrangement of the second grid structure may be determined by the arrangement of the first grid structure. For example, the second grid structure has substantially the same structure as the first grid structure.

Referring to FIG. 5A, each first convex portions CVP1 may have substantially the same width W0. The width W0 may be determined in consideration of a width of the embedded micro-cavity. The width W0 may be about 10 um or less, for example, about 0.1 um to about 3 um.

Referring to FIGS. 5B and 5C, a width of a first convex portion CVP1 adjacent to an end of the liquid crystal layer is greater than a width of a first convex portion CVP1 adjacent to another end of the liquid crystal layer. For example, the width of the first convex portions CVP1 of the first grid structure may be gradually increased in the first direction D1 of the embedded micro-cavity. Alternatively, the width of the first convex portions CVP1 of the first grid structure may be gradually increased in an opposite direction of the first direction D1.

A first width W1 may be defined as a width of a relatively narrow first convex portion CVP1. A second width W2 may be defined as a width of a first convex portion adjacent to a first convex portion having the first width W1. The second width W2 may be larger than the first width W1.

Therefore, when a width of a first convex portion CVP1 adjacent to an end of the liquid crystal layer is greater than a width of a first convex portion CVP1 adjacent to another end of the liquid crystal layer, the alignment liquid 310 may clot at a position where a widest first convex portion CVP1 of the first convex portions CVP1 is located. For example, the alignment liquid 310 may clot at a side surface of the embedded micro-cavity. A black matrix BM may be formed on a side surface of the embedded micro-cavity and corresponds to a non-display area. Accordingly, the display quality may not decrease, even though the alignment liquid 310 clots.

Referring to FIG. 5D, the width of a first convex portion CVP1 adjacent to a middle of the liquid crystal layer may be greater than the width of a first convex portion CVP1 adjacent to an end of the liquid crystal.

A third width W3 may be defined as a width of a relatively narrow first convex portion CVP1. A fourth width W4 may be defined as a width of a first convex portion CVP1 adjacent to a first convex portion having the third width W3. The fourth width W4 may be greater than the third width w3.

When a width of a first convex portion CVP1 adjacent to a middle of the liquid crystal layer is greater than a width of a first convex portion CVP1 adjacent to an end of the liquid crystal layer, the alignment liquid 310 may clot at a position where a widest first convex portion CVP1 of the first convex portions CVP1 is located or the alignment liquid 310 may barely clot. For example, the alignment liquid 310 may clot at a middle of the embedded micro-cavity or the alignment liquid 310 may barely clot.

Accordingly, the width of the first convex portions CVP1 may be controlled, thus controlling the position where the alignment liquid 310 clots when forming the alignment layer 320. For example, the width of the first convex portions CVP1 may be controlled, thus allowing the alignment liquid 310 to clot in a non-display area.

Thus, liquid crystal may be injected into the whole embedded micro-cavity, thus preventing light leakage.

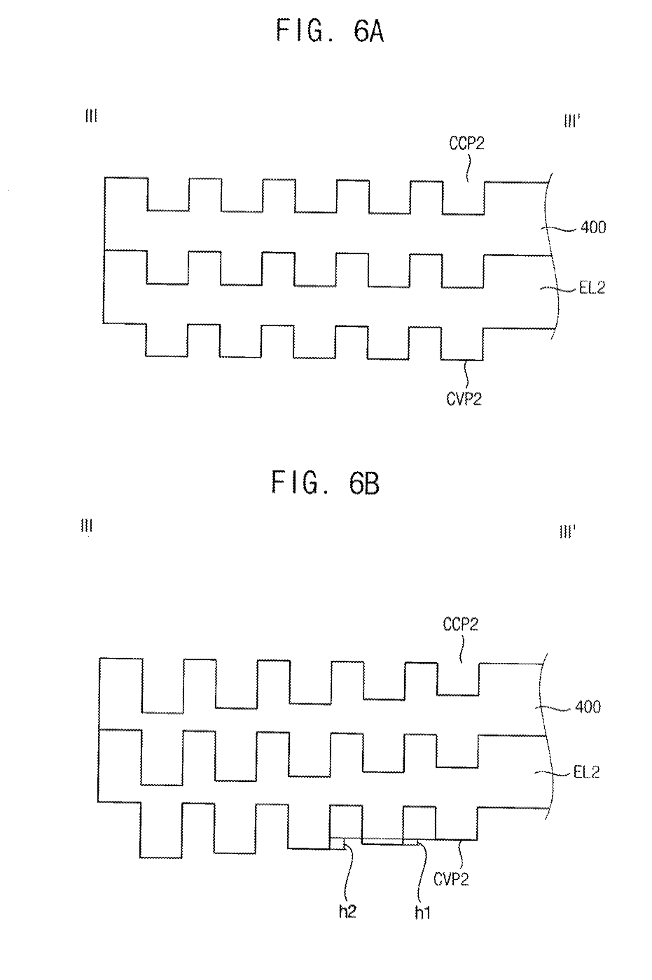

FIGS. 6A and 6B are cross-sectional views taken along line III-III′ in FIG. 3 according to exemplary embodiments of the present invention.

Referring to FIGS. 4A to 4D, 5A to 5D, and 6A and 6B, the first grid structure may include the plurality of first convex portions CVP1 each of which is spaced apart from each other in the first direction D1, and a plurality of second convex portions CVP2 each of which is spaced apart from each other in the second direction D2. The second grid structure may include a plurality of first concave portions CCP1 each of which is spaced apart from each other in the first direction D1 and a plurality of second concave portion CCP2 each of which is spaced apart from each other in the second direction D2.

The first convex portion CVP1 and the first concave portion CCP1 may extend in the second direction D2 that is substantially perpendicular to the first direction D1. The second convex portion CVP2 and the second concave portion CCP2 may extend in the first direction D1.

Referring to FIGS. 6A and 6B, the second grid structure may be substantially similar to the first grid structure. Moreover, the arrangement of the second grid structure may be determined by the arrangement of the first grid structure. For example, the second grid structure has substantially the same structure as the first grid structure.

Referring to FIG. 6A, each of the second convex portions CVP2 may have substantially the same height. The height of the second convex portions CVP2 may be set in consideration of a height of the embedded micro-cavity. The height of the second convex portions CVP2 may be about 10 um or less, for example, about 0.1 to about 3 um.

Referring to FIG. 6B, a height of a second convex portion CVP2 adjacent to an end of the liquid crystal layer is greater than a height of a second convex portion CVP2 adjacent to another end of the liquid crystal layer. For example, the height of the second convex portions CVP2 may be gradually increased in the second direction D2 of the embedded micro-cavity. Alternatively, the height of the second convex portions CVP2 may be gradually increased in an opposite direction of the second direction D2.

A first height h1 and a second height h2 each may be defined as a height difference between second convex portions CVP2 adjacent to each other. The second height h2 may be greater than the first height h1.

When a height of a second convex portion CVP2 adjacent to an end of the liquid crystal layer is greater than a height of a second convex portion CVP2 adjacent to another end of the liquid crystal layer, the alignment liquid 310 may clot at a position where a highest second convex portion CVP2 of the second convex portions CVP2 is located. For example, the alignment liquid 310 may clot at a side surface of the embedded micro-cavity. A black matrix BM may be formed on a side surface of the embedded micro-cavity, corresponding to a non-display area. Accordingly, the display quality might not be deteriorated, even though the alignment liquid 310 clots.

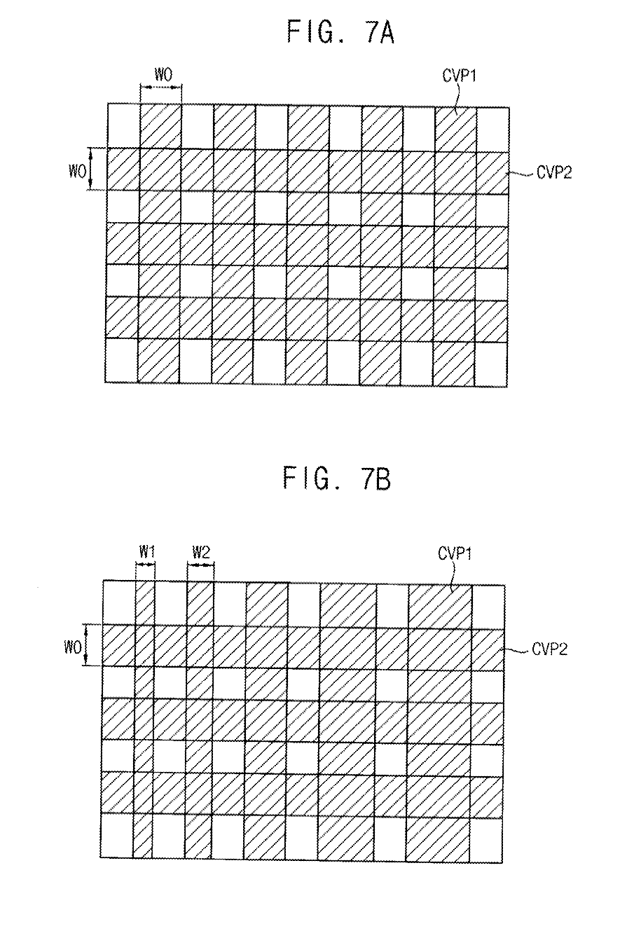

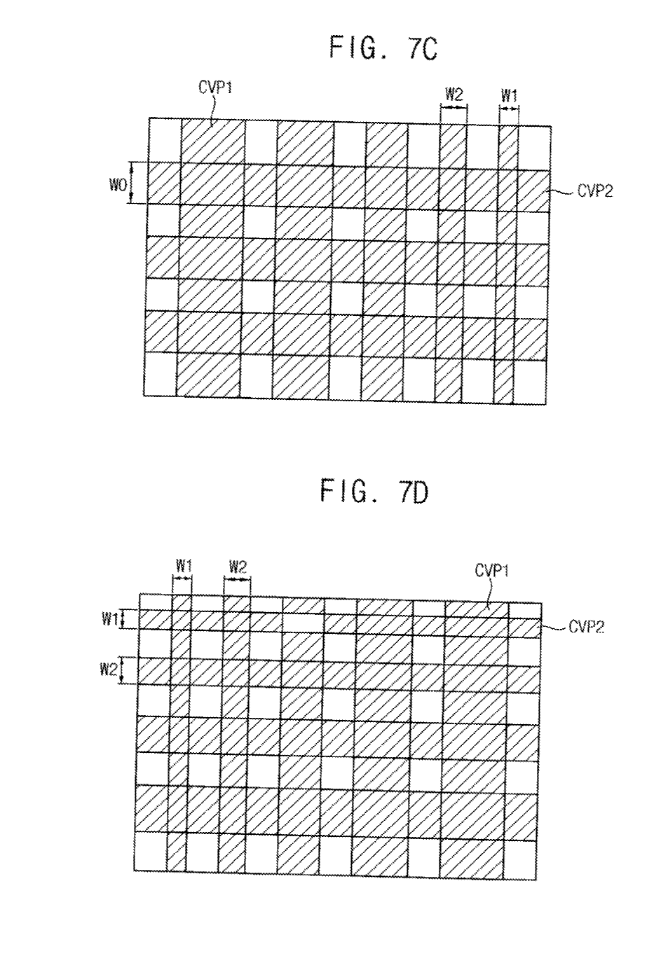

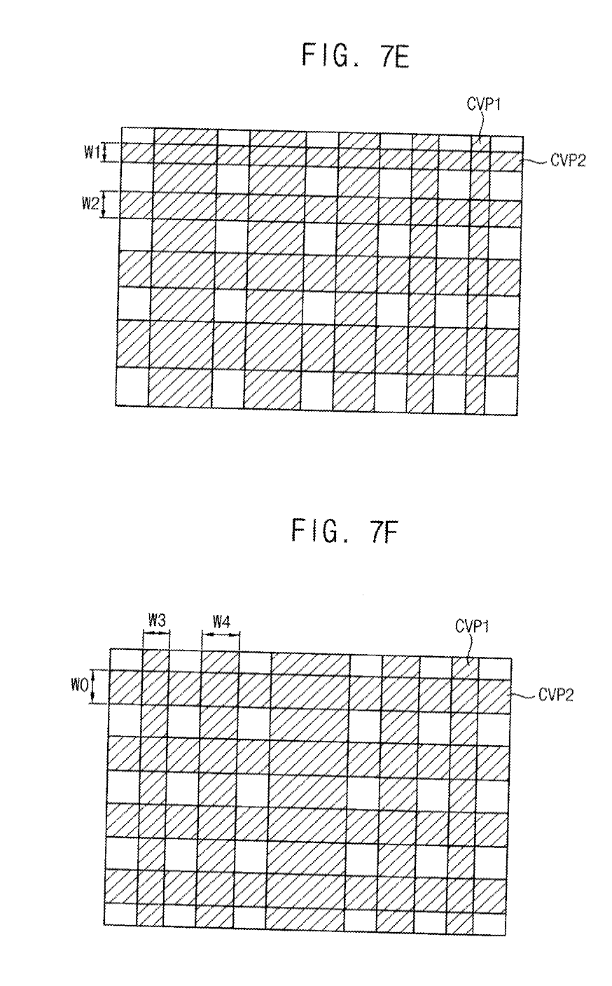

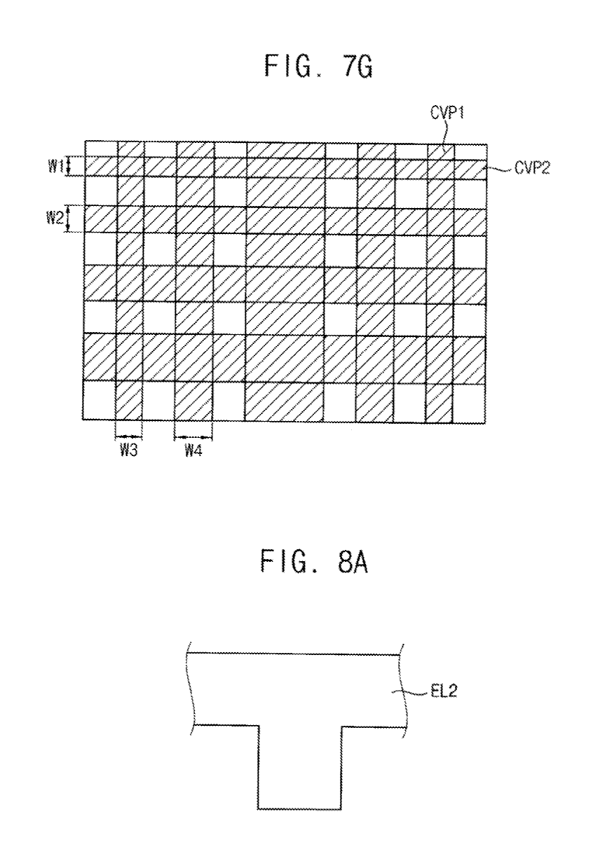

FIGS. 7A to 7G are plan views illustrating grid structures according to exemplary embodiments of the present invention. The second grid structure may be substantially similar to the first grid structure. Moreover, the arrangement of the second grid structure may be determined by the arrangement of the first grid structure. For example, the second grid structure has substantially the same structure as the first grid structure.

Referring to FIG. 7A, the first convex portions CVP1 and the second convex portion CVP2 may have substantially the same width W0. The width W0 may be controlled in consideration of a width of the embedded micro-cavity. The width W0 may be about 10 um or less, for example, about 0.1 um to about 3 um.

A first grid structure including the first convex portions CVP1 and the second convex portions CVP2 may provide increased durability against flexing, twisting and horizontal load, as compared with a first grid structure only including the first convex portions CVP1 and the first concave portions CCP1.

Referring to FIGS. 7B and 7C, a width of a first convex portion CVP1 adjacent to an end of the liquid crystal layer is greater than a width of a first convex portion CVP1 adjacent to another end of the liquid crystal layer. The width of the second convex portions CVP2 may be substantially identical to width W0. The width of the first convex portions CVP1 may be gradually increased in the first direction D1 of the embedded micro-cavity. Alternatively, the width of the first convex portions CVP1 may be gradually increased in an opposite direction of the first direction D1.

A first width W1 may be defined as a width of a relatively narrow first convex portion CVP1 of the first convex portions CVP1, and a second width W2 may be defined as a width of a relatively broad first convex portion CVP1 of the first convex portions CPV1. The second width W2 may be greater than the first width W1.

When the width of a first convex portion CVP1 adjacent to an end of the liquid crystal layer is greater than the width of a first convex portion CVP1 adjacent to another end of the liquid crystal layer, the alignment liquid 310 may clot at a position where a widest first convex portion CVP1 of the first convex portions CVP1 is located. For example, the alignment liquid 310 may clot at a side surface of the embedded micro-cavity. A black matrix BM may be formed on a side surface of the embedded micro-cavity, corresponding to a non-display area. Accordingly, the display quality might not be deteriorated even though the alignment liquid 310 clots.

Referring to FIGS. 7D and 7E, the width of a first convex portion CVP1 adjacent to an end of the liquid crystal layer may be greater than the width of a first convex portion CVP1 adjacent to another end of the liquid crystal layer. The width of a second convex portion CVP2 adjacent to an end of the liquid crystal layer may be greater than the width of a second convex portion CVP2 adjacent to another end of the liquid crystal layer. The width of the first convex portions CVP1 may be gradually increased in the first direction D1 of the embedded micro-cavity or in an opposite direction of the first direction D1, and width of the second convex portions CVP2 may be gradually increased in the second direction D2 of the embedded micro-cavity or in an opposite direction of the second direction D2.

When the width of a first convex portion CVP1 adjacent to an end of the liquid crystal layer is greater than a width of a first convex portion CVP1 adjacent to another end of the liquid crystal layer and the width of a second convex portion CVP2 adjacent to an end of the liquid crystal layer is greater than a width of a second convex portion CVP2 adjacent to another end of the liquid crystal layer, the alignment liquid 310 may clot at a position where a first convex portion CVP1 having the largest width among the first convex portions CVP1 and a first convex portion CVP2 having the largest width among the second convex portions CVP2 are located. For example, the alignment liquid 310 may clot at a side surface of the embedded micro-cavity. A black matrix BM may be formed on a side surface of the embedded micro-cavity, corresponding to a non-display area. Accordingly, the display quality might not be deteriorated, even though the alignment liquid 310 clots.

Referring to FIG. 7F, the width of a first convex portion CVP1 adjacent to a middle of the liquid crystal layer may be greater than the width of a first convex portion CVP1 adjacent to an end of the liquid crystal layer. The width of the second convex portions CVP2 may be substantially identical to width W0.

A third width W3 may be defined as a width of a relatively narrow first convex portion CVP1, and a fourth width W4 may be defined as a width of a relatively broader first convex portion CVP1. The fourth width W4 may be greater than the third width W3.

When a width of a first convex portion CVP1 adjacent to a middle of the liquid crystal layer is greater than a width of a first convex portion CVP1 adjacent to an end of the liquid crystal layer and each of the second convex portions CVP2 has substantially the same width W0, the alignment liquid 310 may clot at a position where a first convex portion CVP1 having the largest width among the first convex portions CVP1 and a second convex portion CVP2 having the largest width among the second convex portions CVP2 are located or the alignment liquid 310 may barely clot. For example, the alignment liquid 310 may clot at a middle of the embedded micro-cavity or the alignment liquid 310 may barely clot.

Referring to FIG. 7G, the width of a first convex portion CVP1 adjacent to a middle of the liquid crystal layer may be greater than the width of a first convex portion CVP1 adjacent to an end of the liquid crystal layer. The width of a second convex portion CVP2 adjacent to an end of the liquid crystal layer may be greater than the width of a second convex portion CVP2 adjacent to another end of the liquid crystal layer.

The width of the first convex portions CVP1 may be gradually increased in the first direction D1 of the embedded micro-cavity toward the middle of the embedded micro-cavity. The width of the second convex portions CVP2 may be gradually increased in the second direction D2 of the embedded micro-cavity. Alternatively, the width of the second convex portions CVP2 may be gradually increased in an opposite direction of the second direction D2.

When a width of a first convex portion CVP1 adjacent to a middle of the liquid crystal layer is greater than a width of a first convex portion CVP1 adjacent to an end of the liquid crystal layer and a width of a second convex portion CVP2 adjacent to an end of the liquid crystal layer is greater than a width of a second convex portion CVP2 adjacent to another end of the liquid crystal layer, the alignment liquid 310 may clot at a position where a first convex portion CVP1 having the largest width among the first convex portions CVP1 and a second convex portion CVP2 having the largest width among the second convex portions CVP2 are located, or the alignment liquid 310 may barely clot.

For example, the alignment liquid 310 may clot in a middle portion of the embedded micro-cavity in the first direction D1 and in an upper portion of the embedded micro-cavity in the second direction D2 or the alignment liquid 310 might not clot. The alignment liquid 310 may clot in a middle portion of the embedded micro-cavity in the first direction D1 and in a lower side of the embedded micro-cavity in the second direction D2 or the alignment liquid 310 might not clot.

When a width of a first convex portion CVP1 adjacent to an end of the liquid crystal layer is greater than a width of a first convex portion CVP1 adjacent to another end of the liquid crystal layer, the alignment liquid 310 may clot at a position where a first convex portion CVP1 having the largest width among the first convex portions CVP1 and a second convex portion CVP2 having the largest width among the second convex portions CVP2 are located. For example, the alignment liquid 310 may clot at a side surface of the embedded micro-cavity. A black matrix BM may be formed on a side surface of the embedded micro-cavity, corresponding to a non-display area. Accordingly, the display quality might not be deteriorated, even though the alignment liquid 310 clots.

Accordingly, the width of the first concave portions CVP1 and the width of the second concave portions CVP2 may be controlled, and thus, the position where the alignment liquid 310 clots may be controlled when forming the alignment layer 320. For example, the width of the first concave portion CVP1 and the second concave portion CVP2 may be controlled, thus allowing the alignment liquid 310 to clot in a non-display area.

Thus, the liquid crystal may be injected into the whole embedded micro-cavity, thus decreasing light leakage.

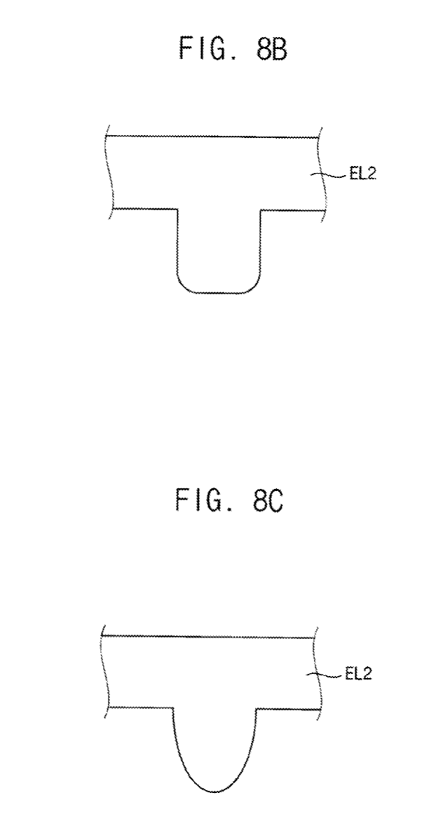

FIGS. 8A to 8C are enlarged views each illustrating a portion of a first or second convex portion according to exemplary embodiments of the present invention.

Referring to FIGS. 8A to 8C, the first convex portion or the second convex portion may have a right-angled corner, a rounded corner, or an elliptical corner.

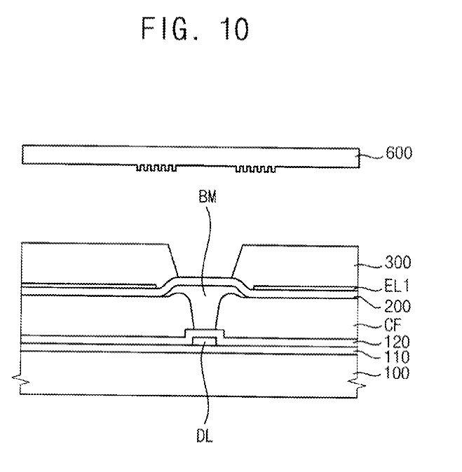

The right-angled corner, the rounded corner and the elliptical corner may be formed by a nano-imprinting method, a halftone mask method or a slit mask method. The nano-imprinting method, the halftone mask method and the slit mask method will be described below in detail referring to FIGS. 10A to 12B.

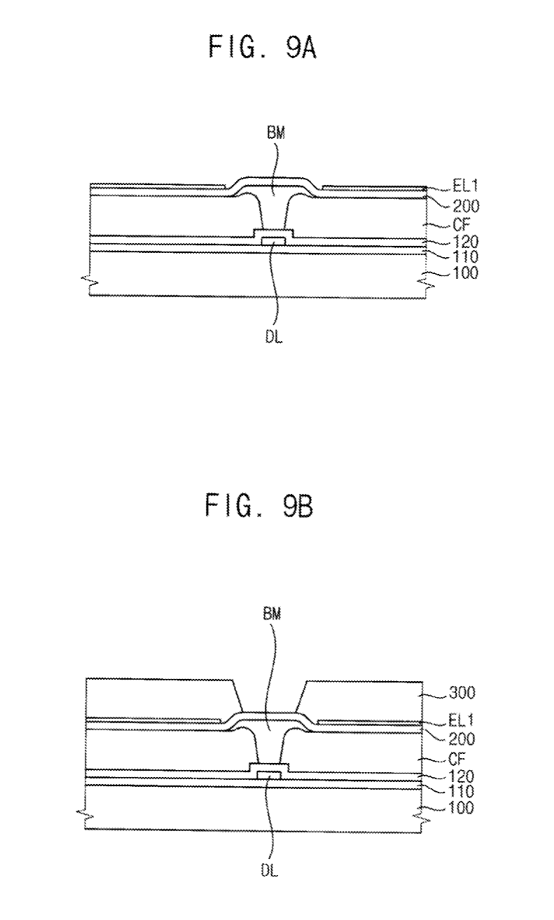

FIGS. 9A and 9B are cross-sectional views illustrating a method of forming a sacrificial layer according to an exemplary embodiment of the present invention.

Referring to 9A, a first electrode EL1 and a first insulation layer 200 are formed on a substrate 100.

For example, before forming the first electrode EL1, a gate insulation layer 110, a data insulation layer 120, a color filter CF and a black matrix BM may be formed on the substrate 100.

As illustrated in FIGS. 3 and 9A, a gate pattern including a gate electrode GE and a gate line GL may be formed on the substrate 100. A first conductive layer may be formed on the substrate 100 and may be patterned by a photolithograph process, thus forming the gate pattern.

The gate insulation layer 110 may be formed on the substrate 100, covering the gate pattern. The gate insulation layer 110 may insulate the gate pattern.

A semiconductor pattern SM may be formed on the gate insulation layer 110. The semiconductor pattern SM may overlap the gate electrode GE.

A data pattern including a data line DL, a source electrode SE and a drain electrode DE may be formed on the gate insulation layer 110 on which the semiconductor pattern SM is formed. A second conductive layer may be formed on the insulation layer 110 and may be patterned by a photolithography process, thus forming the data pattern.

The drain electrode DE may be spaced apart from the source electrode SE on the semiconductor pattern SM. The semiconductor pattern SM may have a conductive channel between the source electrode SE and the drain electrode DE.

The TFT may include the gate electrode GE, the source electrode SE, the drain electrode DE and the semiconductor pattern SM.

The data insulation layer 120 may be formed on the gate insulation layer 110 on which the data pattern is formed. The color filter CF may be formed on the data insulation layer 120. The color filter may include a red color filter, green color filter and a blue color filter. The color filter may be formed by an organic macromolecular material. The color filter CF may be formed by a photolithography process using a photosensitive macromolecular material. Alternatively, the color filter may be formed by an inkjet process.

The black matrix BM may be formed on the data insulation layer 120 on which the color filter CF is formed. The black matrix BM may overlap the gate pattern and/or data pattern.

As illustrated in FIG. 2, in accordance with an exemplary embodiment of the present invention, the display panel has a structure such as a COA (Color filter On Array) structure and a BOA (Black matrix On Array) structure. In the COA structure, the color filter is formed on a lower surface of the liquid crystal layer. In the BOA structure, the black matrix is formed on a lower surface of the liquid crystal layer. Alternatively, the color filter or the black matrix may be formed on an upper surface of the liquid crystal layer.

The first insulation layer 200 may be formed on the color filter CF. The first insulation layer 200 may be formed on a whole surface of the substrate 100.

The first insulation layer 200 may include an insulation material. For example, the first insulation layer 200 may include SiNx or SiOx.

The first electrode EL1 may be disposed on the first insulation layer 200. The first electrode EL1 may be disposed on the pixel area.

The first electrode EL1 may have a slit pattern. A first electrode conductive layer may be formed on the first electrode EL1 and may be patterned by a photolithography process, thus forming the slit pattern. For example, the first electrode EL1 may include a transparent conductive material such as indium tin oxide (ITO), indium zinc oxide (IZO) and aluminum zinc oxide (AZO).

Referring to 9B, a sacrificial layer 300 is formed on the substrate 100.

A first photoresist composition layer may be coated on the first insulation layer 200 and the first electrode EL1, thus forming the sacrificial layer 300. The sacrificial layer 300 may correspond to the pixel area.

The sacrificial layer 300 may be removed, providing a space for forming a tunnel-shaped cavity. Accordingly, the sacrificial layer 300 may be formed at a position where the liquid crystal layer (LC) is formed. The sacrificial layer 300 may determine a width and height of the tunnel-shaped cavity.

The first photoresist composition may include a positive photoresist. The positive photoresist may be an organic material including, e.g., a novolak resin. For example, the sacrificial layer 300 may include a positive novolak photoresist. The sacrificial layer 300 may be formed by deposition and ashing processes or by deposition and polishing processes. Alternatively, the sacrificial layer 300 may be formed by an inkjet process or a spin-coating process.

FIG. 10 is a cross-sectional view illustrating forming a grid structure in a sacrificial layer using a nano-imprinting process.

Referring to FIG. 10, a grid structure is formed in the sacrificial layer 300 by a nano-imprinting process.

A template 600 may include a first pattern having a plurality of protrusions on a first surface thereof. The template 600 may form a grid structure including a second pattern on a grid area GA of the sacrificial layer 300. The second pattern corresponds to the first pattern. The plurality of protrusions may define raised portions and depressed portions, which are sequentially arranged.

When forming the grid structure on the sacrificial layer 300, a first surface of the template 600 including a plurality of protrusions may contact the sacrificial layer 300. The template 600 may be exposed to light. The sacrificial layer 300 including the second pattern may be hardened. The template 600 may be removed from the hardened sacrificial layer 300. A second electrode may be formed on the sacrificial layer 300. A second insulation layer may be formed on the second electrode.

The template 600 may be arranged corresponding to the grid area GA. The template 600 may be arranged over the sacrificial layer 300 such that the first surface of the template 600 including a plurality of the protrusions may face the sacrificial layer 300. The template 600 and the sacrificial layer 300 may be pressurized, thus contacting each other. For example, a pressure may be applied to a second surface of the template that is opposite to the first surface of the template. Therefore, the grid structure including the second pattern corresponding to the first pattern may be formed on the sacrificial layer 300.

The grid structure includes the second pattern on the sacrificial layer 300. The template 600 may be pressurized and may contact the sacrificial layer 300. The grid structure may be hardened by applying heat and/or ultraviolet light to the grid structure. The template 600 may be penetrated by the ultraviolet light.

The template 600 may be removed after hardening the grid structure of the sacrificial layer 300. When the template 600 is removed, depressed portions corresponding to the raised portions of the template 600 and raised portions corresponding to the depressed portions of the template 600 may be formed on the sacrificial layer 300.

Referring to FIGS. 8A and 10, a corner of the first convex portion CVP1 or the second convex portion CVP2 may have a rectangular shape by controlling the shapes of the protrusions of the template 600. For example, the corner of the first convex portion CVP1 or the second convex portion CVP2 may have various shapes by controlling the structure of the raised portion and the depressed portion of the template 600.

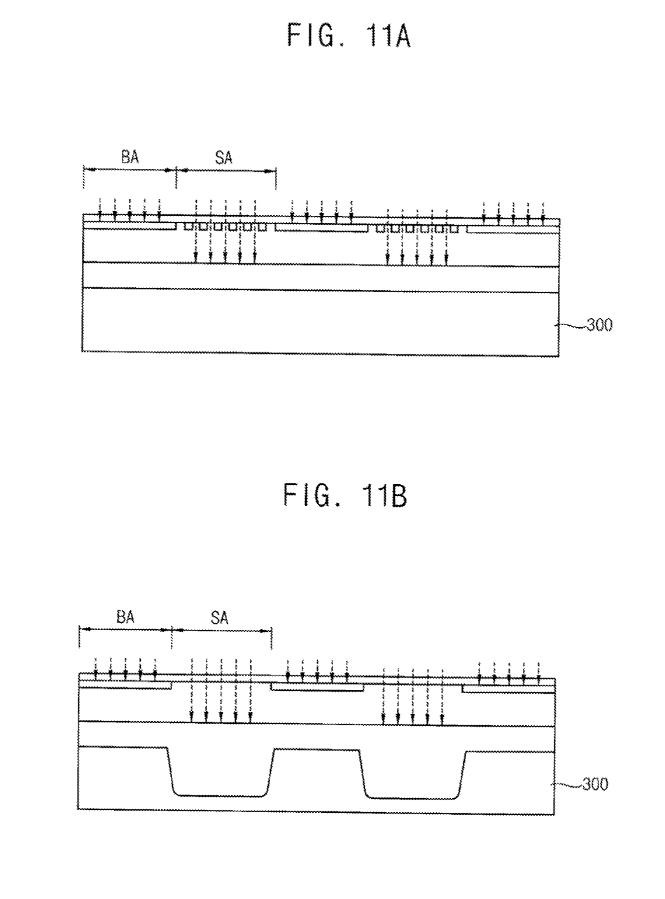

FIGS. 11A and 11B are cross-sectional views illustrating a method of forming a grid structure on a sacrificial layer using a slit mask according to an exemplary embodiment of the present invention.

Referring to FIGS. 11A and 11B, a slit mask may be used to form a grid structure on a sacrificial layer 300.

The slit mask may include a blocking area BA having a light blocking pattern and a slit area SA having a slit pattern. The slit mask may be aligned on the sacrificial layer 300, and light may be radiated onto the slit mask.

The blocking pattern and the slit pattern may include chromium or chromium oxide.

Light directed to the blocking area may be blocked by the light blocking pattern, and light directed to the slit area may pass through the slit pattern to the sacrificial layer 300.

Then, the sacrificial layer 300 exposed by the slit mask may be developed by a developer, thus forming a plurality of convex portions on the sacrificial layer 300.

The slit pattern, for example, may have a plurality of patterns. Each of the patterns may be spaced apart from each other by a predetermined interval. Alternatively, the slit pattern may have various types of slit patterns, thus allowing the grid structure including the first convex portion CVP1 and the second convex portion CVP2 to have various shapes.

For example, the slit pattern may have a narrow slit to transmit light. Alternatively, the slit pattern may have a wide slit to transmit a large amount of light.

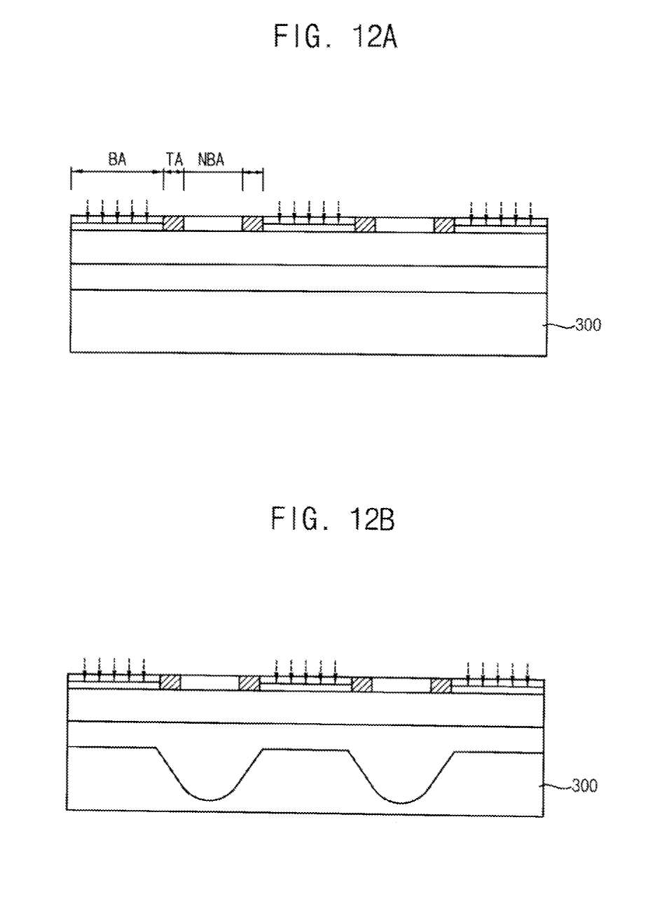

FIGS. 12A and 12B are cross-sectional views illustrating a method of forming a grid structure on a sacrificial layer using a half-tone mask according to an exemplary embodiment of the present invention.

Referring to FIGS. 12A and 12B, a half-tone mask may be used to form a grid structure on a sacrificial layer 300.

The halftone mask may include a blocking area BA, a non-blocking area NBA and a transflective area TA. The blocking area BA may have a light blocking pattern. The non-blocking area NBA might not have a light blocking pattern. The transflective area TA may have a transflective pattern to decrease the amount of transmitted light. The halftone mask may be aligned on the sacrificial layer 300 and light may be radiated onto the halftone mask.

Accordingly, while light directed to the blocking area BA may be blocked by the light blocking pattern, light directed to the non-blocking area NBA may pass through the halftone mask. The transflective area TA having the transflective pattern may decrease the amount of the transmitted light.

The sacrificial layer 300 exposed to light by the halftone mask may be developed by a developer, thus forming a plurality of convex portions on the sacrificial layer 300.

The blocking area BA may include chromium Cr or chromium oxide. The transflective area TA may include substantially the same material as the blocking area BA. The transflective area TA may include a slit. The transflective area TA may include CrxOy, CrxCoy, CrxCoyNz, or SizNy (x, y, and z each represent a positive integer) that may be disposed on a transparent substrate of the halftone mask.

A second electrode EL2 may be disposed on the second insulation layer 400. The second electrode EL2 may be arranged corresponding to a pixel area. The second electrode EL2 may include a transparent conductive material such as indium tin oxide (ITO), indium zinc oxide (IZO) and/or aluminum zinc oxide (AZO).

FIGS. 13A to 13I are cross-sectional views illustrating a method of removing a sacrificial layer and forming an alignment layer by an alignment liquid according to an exemplary embodiment of the present invention.

Referring to FIGS. 13A and 13B, the second electrode EL2 may be disposed on the sacrificial layer 300 having a first grid structure. The second electrode EL2 may be arranged corresponding to a pixel area. Therefore, the second electrode EL2 has substantially the same structure as the sacrificial layer 300.

The second electrode EL2 may include a transparent conductive material such as indium tin oxide (ITO), indium zinc oxide (IZO) and aluminum zinc oxide (AZO).

Referring to FIG. 13C, a second insulation layer 400 may be formed on the second electrode EL2 including the grid structure formed. The second insulation layer 400 may be disposed corresponding to the first grid structure of the second electrode EL2. Therefore, the second insulation layer 400 has substantially the same grid structure as the sacrificial layer 300 and the second electrode EL2.

The second insulation layer 400 may include an insulation material. For example, the second insulation layer 400 may include SiNx or SiOx.

Referring to FIG. 13D, a second photoresist composition layer PR2 is coated on the second insulation layer 400.

The second photoresist composition layer PR2 might not be formed on a position corresponding to a developer injection region that is used as a pathway for removing the sacrificial layer 300. Therefore, the second photoresist composition layer PR2 may expose a part of the second insulation layer 400.

Referring to FIGS. 3 and 13D, the grid area may be formed adjacent to the developer injection region, thus providing resistance to flexing, twisting and horizontal load.

The second photoresist composition layer PR2 may protect a portion of the second insulation layer 400. Thus, the covered portion of the second insulation layer 400 might not be eliminated by the developer during removing the sacrificial layer 300. For example, the second photoresist composition layer PR2 may cover the second insulation layer 400 and the second electrode EL2 except for a portion corresponding to the developer injection region.

The second photoresist composition layer PR2 may include a negative photoresist. The negative photoresist may be an organic material including, e.g., an acryl resin. For example, the second photoresist composition layer PR2 may include negative acryl photoresist. Furthermore, the second photoresist composition layer PR2 may further include an ultraviolet curable agent and/or a thermosetting agent.

Referring to FIG. 13E, light may be radiated onto the entire surface of the substrate.

The second photoresist composition layer PR2 and the sacrificial layer 300 may be exposed to light. The second photoresist composition layer PR2 including a negative photoresist is hardened by the light exposure. The sacrificial layer 300 including a positive photoresist may be dissolved and transformed by the light exposure and may be removed by a developing process.

The intensity of light used for the light exposure may be in a range from about 300 mJ to about 3J. The wavelength of the light may be about 365 nm.

Referring to FIG. 13F, a developer injection region is formed on the sacrificial layer 300.

The second photoresist composition layer PR2 may expose a portion of the second insulation layer 400 between pixel areas adjacent to each other.

The exposed portion of the second insulation layer 400 may be partially removed by an etching process. Therefore, the sacrificial layer 300 may be exposed, thus forming a developer injection hole DI.

The second photoresist composition layer PR2 may function as a mask, and the partially exposed portion of the second insulation layer 400 may be etched corresponding to the developer injection region.

Referring to FIGS. 13F and 13G, a developer may be injected to the sacrificial layer 300 through the developer injection hole DI. The developer eliminates the sacrificial layer 300. The sacrificial layer 300 may be easily removed by the developer because the sacrificial layer 300 is previously transformed by the light exposure. A tunnel-shaped cavity may be formed by removing the sacrificial layer 300 by developer. The tunnel-shaped cavity may be formed at a space where the sacrificial layer 300 is removed.

The developer may include an alkali solution. For example, the developer may include about 90% or more of water and 10% or less of alkali component. The developer only removes the sacrificial layer 300. For example, the developer may include about 2.38% of tetramethylammonium hydroxide (TMAH) or about 1% of potassium hydroxide (KOH).

The removal of the sacrificial layer 300 by the developer may be performed at about 23° C. to about 26° C. The removal of the sacrificial layer 300 may be accelerated by increasing the processing temperature. For example, the sacrificial layer 300 may be removed by the developer at about 23° C. to about 80° C.

Referring to FIGS. 13H and 13I, an alignment layer 320 may be formed in the tunnel-shaped cavity that is obtained by removing the sacrificial layer 300. The alignment layer 320 may be disposed in the tunnel-shaped cavity on an upper surface of the first insulation layer 200 and the first electrode EL1. The alignment layer 320 may be disposed in the tunnel-shaped cavity on a lower surface of the second insulation layer 200 and the second electrode EL2. The alignment layer 320 may be formed by an alignment liquid. The alignment liquid may be obtained by mixing an alignment material such as polyimide (PI) with a solvent. The alignment liquid may flow into the tunnel-shaped cavity by capillary action. For example, the alignment liquid may be provided into the tunnel-shaped cavity through a developer injection hole DI.

The alignment liquid may be provided into the tunnel-shaped cavity by using an inkjet having a micropipette or using a vacuum injection apparatus. The solvent may be removed from the alignment liquid by leaving the substrate 100 at room temperature or by heating the substrate 100.

However, the alignment layer 320 may be omitted in accordance with the type of the liquid crystal layer LC or the structure of the first electrode EL1 and the second electrode EL2. For example, when the first electrode EL1 has a micro slit, and thus, the liquid crystal molecules may be aligned without the alignment layer, the alignment layer 320 may be omitted. Alternatively, when a reactive mesogen layer for aligning the liquid crystal molecules is formed, the alignment layer 320 may be omitted.

A liquid crystal layer LC may be formed in the tunnel-shaped cavity in which the alignment layer 320 is formed. The liquid crystal layer LC may include a liquid crystal. The liquid crystal is provided as a fluid. The liquid crystal may flow into the tunnel-shaped cavity by capillary action. For example, the liquid crystal may be provided into the tunnel-shaped cavity through a developer injection hole DI.

The liquid crystal may be provided into the tunnel-shaped cavity by using an inkjet having a micropipette. Alternatively, the liquid crystal may be provided into the tunnel-shaped cavity by using a vacuum injection apparatus. When using the vacuum injection apparatus, the developer injection hole DI may be immersed in the chamber including a liquid crystal material. When the pressure of the chamber decreases, the liquid crystal may be drawn into the tunnel-shaped cavity by capillary action.

In an exemplary embodiment of the present invention, instead of the liquid crystal layer LC, the display panel may include an image display layer displaying an image. For example, the image display layer may be an electrophoretic layer. The electrophretic layer may include an insulation medium and charged particles. The insulation medium may be a dispersion medium. The charged particles have electrophoretic properties.

A lower polarizer may be attached onto a lower surface of the substrate 100, and an upper polarizer may be attached onto an upper surface the protection layer 500. The upper polarizer may include an adhesive layer, thus adhering to the protection layer 500.

In accordance with exemplary embodiments of the present invention, an embedded micro-cavity display panel includes an electrode and an insulation layer each having a grid structure, thus increasing durability. Therefore, the embedded micro-cavities may be prevented from deforming. The height and width of the grid structure may be controlled, and thus, the position where the alignment liquid clots may be controlled, thus preventing light leakage.

Although exemplary embodiments of the present invention have been described, it is understood that the present invention should not be limited to these exemplary embodiments and various changes and modifications can be made by one of those ordinary skilled in the art within the spirit and scope of the present invention as hereinafter claimed.

What is claimed is:

1. A display panel, comprising:
a substrate including a thin film transistor (TFT);
a first insulation layer disposed on the substrate;
a first electrode disposed on the first insulation layer and electrically connected to the TFT;
a second electrode disposed on the liquid crystal layer and including a first grid structure;
a liquid crystal layer disposed between the first electrode and the second electrode; and
a second insulation layer disposed on the second electrode and including a second grid structure.

2. The display panel of claim 1, further comprising a gate line electrically connected to the TFT and extending in a first direction;
wherein the first grid structure comprises a plurality of first convex portions each of which is spaced apart from each other in the first direction, and the second grid structure comprises a plurality of first concave portions each of which is spaced apart from each other in the first direction, and
wherein the plurality of first convex portions and the plurality of first concave portions extend in a second direction which is substantially perpendicular to the first direction.

3. The display panel of claim 2, wherein a height of a first convex portion adjacent to an end of the liquid crystal layer is greater than a height of a first convex portion adjacent to an opposite end of the liquid crystal layer.

4. The display panel of claim 2, wherein a width of a first convex portion adjacent to an end of the liquid crystal layer is greater than a width of a first convex portion adjacent to an opposite end of the liquid crystal layer.

5. The display panel of claim 2, wherein a height of a first convex portion adjacent to a middle of the liquid crystal layer is greater than a height of a first convex portion adjacent to an end of the liquid crystal layer.

6. The display panel of claim 2, wherein a width of a first convex portion adjacent to a middle of the liquid crystal layer is greater than a width of a first convex portion adjacent to an end of the liquid crystal layer.

7. The display panel of claim 2, wherein the first grid structure further comprises a plurality of second convex portions each of which is spaced apart from each other in the second direction, and the second grid structure further comprises a plurality of second concave portions each of which is spaced apart from each other in the second direction.

8. The display panel of claim 7, wherein the plurality of second convex portions and the plurality of second concave portions extend in the first direction.

9. The display panel of claim 7, wherein a height of a second convex portion adjacent to an end of the liquid crystal layer is greater than a height of a second convex portion adjacent to an opposite end of the liquid crystal layer.

10. The display panel of claim 7, wherein a width of a second convex portion adjacent to an end of the liquid crystal layer is greater than a width of a second convex portion adjacent to an opposite end of the liquid crystal layer.

11. The display panel of claim 7, wherein the first convex portion and the second convex portion each have a right-angled corner.

12. The display panel of claim 7, wherein the first convex portion and the second convex portion each have a rounded corner.

13. The display panel of claim 7, wherein the first convex portion and the second convex portion each have an elliptical corner.

14. A method of manufacturing a display panel, the method comprising:
forming a first insulation layer on a substrate including a thin film transistor (TFT);
forming a sacrificial layer on the first insulation layer by coating a first photoresist composition layer;
forming a grid structure on the sacrificial layer;
forming a second insulation layer on the sacrificial layer;
removing the sacrificial layer with a developer; and
forming a liquid crystal layer in a space where the sacrificial layer was removed.

15. The method of claim 14, further comprising:
forming a first electrode on the first insulation layer after forming the first insulation layer; and
forming a second electrode on the sacrificial layer prior to forming the second insulation layer.

16. The method of claim 14, further comprising:
forming a developer injection region that exposes a portion of the sacrificial layer.

17. The method of claim 16, further comprising:
coating a second photoresist composition layer on a portion of the second insulation layer; and
etching the second insulation layer, exposing the portion of the sacrificial layer.

18. The method of claim 14, further comprising:
forming an alignment layer on an inner surface of a space where the sacrificial layer was removed from; and
injecting a liquid crystal into the space.

19. The method of claim 14, further comprising:
forming a sacrificial layer including a first pattern corresponding to a template, wherein the template has a second pattern with a plurality of protrusions on a first surface of the template;
separating the template from the sacrificial layer; and
forming the second insulation layer on the sacrificial layer.

20. The method of claim 14, further comprising:
exposing light on a mask including a blocking area having a light blocking pattern and a slit area having a slit pattern.

21. The method of claim 14, wherein the forming a grid structure comprises exposing the sacrificial layer to light while arranging a mask on the sacrificial layer, wherein the mask includes a blocking area having a light blocking pattern, a non-blocking area, and a transflective area having a transflective pattern.

22. A display panel, comprising:
a substrate;
a first insulation layer disposed on the substrate;
a first electrode disposed on the first insulation layer;
an image displaying layer disposed on the first electrode;
a second electrode disposed on the image displaying layer, wherein the second electrode includes a plurality of convex protrusions each of which is spaced apart from each other; and
a second insulation layer disposed on the second electrode.
